(19) United States
(12) Patent Application Publication
(10) Pub. No.: US 2024/0222135 A1
(43) Pub. Date: Jul. 4, 2024

(54) METHODS FOR SELECTIVELY FORMING A PASSIVATION LAYER ON A DIELECTRIC SURFACE RELATIVE TO A METALLIC SURFACE, METHODS FOR UTILIZING A PASSIVATION LAYER, AND RELATED STRUCTURES INCLUDING A PASSIVATION LAYER

(71) Applicant: ASM IP Holding B.V., Almere (NL)

(72) Inventors: Daniele Chiappe, Freiburg (DE); Viraj Madhiwala, Heverlee (BE); Eva E. Tois, Espoo (FI); Marko Tuominen, Helsiki (FI); Charles Dezelah, Helsinki (FI); Shaoren Deng, Ghent (BE); Vincent Vandalon, Heverlee (BE); Anirudhan Chandrasekaran, Scottsdale, AZ (US)

(21) Appl. No.: 18/398,598

(22) Filed: Dec. 28, 2023

Related U.S. Application Data
(60) Provisional application No. 63/477,953, filed on Dec. 30, 2022.

(51) Int. Cl. H01L 21/3205; H01L 21/02; H01L 21/3213

(52) U.S. Cl. CPC H01L 21/32051; H01L 21/02068; H01L 21/02118; H01L 21/32135

(57) ABSTRACT

Methods for forming selective passivation layers on a dielectric surface relative to a metallic surface employing a chalcogenide layer are disclosed. Methods for utilizing selective passivation layers for depositing target films as also disclosed. Exemplary structures that include selective passivation layers are further disclosed.

### CROSS-REFERENCE TO RELATED APPLICATION(S)

This application claims the benefit of U.S. Provisional Application 63/477,953 filed on Dec. 30, 2022, the entire contents of which are incorporated herein by reference.

### FIELD OF INVENTION

The present disclosure generally relates to the field of semiconductor processing methods and related structures, and to the field of device and integrated circuit manufacture. More particularly, the present disclosure relates to methods for selectively forming a passivation layer on a dielectric surface relative to metallic surface and methods for utilizing such passivation layers, as well as structures including the passivation layers.

### BACKGROUND OF THE DISCLOSURE

In some applications, it may be desirable to deposit a passivation layer only on certain areas of a substrate. Typically, such discriminating results are achieved by depositing a continuous passivation layer and subsequently patterning the passivation layer using lithography and etch steps. Such lithography and etch processes may be time consuming and expensive, and do not offer the precision required for many applications.

A possible solution is the use of selective deposition processes, whereby a passivation layer is preferentially deposited only in the desired areas thereby eliminating the need for subsequent patterning steps. Selective deposition processes may take a number of forms, including, but not limited to, selective dielectric deposition on dielectric surfaces (DoD), selective dielectric deposition on metallic surfaces (DOM), selective metal deposition on dielectric surfaces (MoD) and selective metal deposition on metallic surfaces (MoM).

Selective deposition of passivation layers that can enable MoM or DoM type selective deposition processes and are of interest for providing simplified methods for depositing a target film (e.g., a dielectric film or a metallic film) over metallic surfaces without the need for complex patterning and etch steps. However, an inability to sufficiently passivate metallic surfaces may negatively impact the selective deposition of passivation layers on dielectric surfaces relative to metallic surfaces. Accordingly, improved methods are desired for the selective deposition of passivation layers on dielectric surfaces relative to metallic surfaces.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

In particular the present disclosure includes methods for selectively forming a passivation layer on a dielectric surface relative to a metallic surface on a substrate, the methods can include, seating a substrate including a first dielectric surface and a second metallic surface within a reaction chamber, contacting the second metallic surface with a chalcogen reactant thereby forming a metal chalcogenide layer including a metal chalcogenide surface. The methods can further include, selectively depositing an organic passivation layer on the first dielectric surface relative to the metal chalcogenide surface, and selectively removing the metal chalcogenide layer.

In some embodiments, the methods can further include, performing a surface clean step on the surface of the substrate prior to contacting the substrate with the chalcogen reactant, wherein the surface clean step removes a native oxide from the second metallic surface.

In some embodiments, the chalcogen reactant comprises, one or more of a sulfur reactant, a selenium reactant, and a tellurium reactant, or combinations thereof.

In some embodiments, the chalcogen in the chalcogen reactant has an oxidation state of −2.

In some embodiments, the chalcogen in the chalcogen reactant has an oxidation state of +2.

In some embodiments, the chalcogen reactant is selected from a group consisting of chalcogenides, chalcogenols, sulfoxides, selenoxides, tellurinyls and elemental chalcogens.

In some embodiments, the chalcogen reactant comprises one or more of H₂S, H₂Se, H₂Te, (CH₃)₂S, (NH₄)₂S, dimethylsulfoxide ((CH₃)₂SO), (CH₃)₂Se, (CH₃)₂Te, elemental or atomic S, Se, Te, H₂S₂, H₂Se₂, H₂Te₂, a chalcogenol with the formula R—Y—H, wherein R is a substituted or a unsubstituted hydrocarbon selected from a C₁-C₈ alkyl or a substituted alkyl, and Y is S, Se, or Te, a thiol with the formula R—S—H, wherein R is substituted or unsubstituted hydrocarbon, and a chalcogen alkylsilyl reactant having the formula (R₃Si)₂Y, wherein R₃Si is an alkylsilyl group and Y is S, Se or Te.

In some embodiments, the chalcogen reactant comprises an energized chalcogen reactant, wherein energizing the chalcogen reactant includes one or more of applying thermal energy to the chalcogen reactant, irradiating the chalcogen reactant with UV or laser irradiation, and generating a plasma from the chalcogen reactant to form chalcogenide based reactive species.

In some embodiments, selectively depositing the organic passivation layer on the first dielectric surface relative to the metal chalcogenide surface comprises, performing multiple deposition cycles of a cyclical deposition process in which the substrate is alternately and sequentially contacted with a first vapor phase organic precursor and a second vapor phase organic precursor.

In some embodiments, the first vapor phase organic precursor comprises a diamine, the second vapor phase organic precursor comprises a dianhydride, and the organic passivation layer comprises a polyimide.

In some embodiments, selectively removing the metal chalcogenide layer further comprises, contacting the substrate with a plasma generated from a gas comprising hydrogen, argon, a halide containing gas, or mixtures and combinations thereof.

In some embodiments, the metal chalcogenide layer comprise one of MoS₂, WS₂, and WSe₂.

In some embodiments, contacting the second metallic surface with the chalcogen reactant is performed at a first process temperature, and selectively depositing the organic passivation layer is performed at second process temperature, wherein the first process temperature is higher than the second process temperature.

The present disclosure can also methods for selectively forming and utilizing a passivation layer on a substrate. The method can comprise, seating a substrate including a first dielectric surface and a second metallic surface within a reaction chamber, and contacting the substrate with an activated chalcogen reactant, thereby converting the second metallic surface to a metal chalcogenide layer including a metal chalcogenide surface. The methods can also include, selectively depositing an organic passivation layer on the first dielectric surface relative to the metal chalcogenide surface by performing multiple deposition cycles of a cyclical deposition process in which the substrate is alternately and sequentially contacted with a first vapor phase organic precursor and a second vapor phase organic precursor. The methods can also include, selectively removing the metal chalcogenide layer by contacting the substrate with one or more reactive species generated from plasma thereby exposing a third metallic surface. The methods can also include, depositing a target film on the third metallic surface, and selectively removing the organic passivation layer preferentially to the target film.

In some embodiments, the metal chalcogenide layer comprises, a self-passivated 2D-dichalcogenide layer selected from the group consisting of MoS₂, WS₂, and WSe₂.

In some embodiments, the activated chalcogen reactant is activated by exposing the chalcogen reactant to a direct plasma or a remote plasma to thereby form chalcogen based reactive species.

In some embodiments, contacting the substrate with the activated chalcogen reactant is performed at a first process temperature, and selectively depositing the organic passivation layer is performed at second process temperature, wherein the first process temperature and the second process temperature are different.

In some embodiments, the activated chalcogen reactant contacts the substrate for time period between 1 minute and 10 minutes.

In some embodiments, the target film comprises one of a dielectric film, an organic film, a metallic film, and a metal oxide film.

In some embodiments, the one or more reactive species employed to selectively remove the metal chalcogenide layer are generated from a gas including, hydrogen, argon, a halide containing gas, and mixture and combinations thereof.

In some embodiments, selectively removing the metal chalcogenide layer further comprises, removing less than 10% of an average thickness of the organic passivation layer.

The present disclosure also includes structures formed according to the methods disclosed herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates an exemplary process for selectively forming a passivation layer on a dielectric surface relative to a metallic surface in accordance with at least one embodiment of the present disclosure;

FIG. 2 illustrates an exemplary selective cyclical deposition process for depositing a passivation layer in accordance with at least one embodiments of the present disclosure;

FIG. 3 illustrates an exemplary process for forming a target film on a metallic surface in accordance with at least one embodiment of the present disclosure; and

FIGS. 4A-F illustrates cross-sectional views of structures formed in accordance with at least one embodiment of the present disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for selectively forming passivation layers suitable for a variety of applications. Exemplary methods can be used, for example, for the selective deposition of a dielectric target film on metallic surfaces, or the selective deposition of a metal target film on metallics surfaces. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying or within the substrate, such as one or more layers formed according to a method as described herein. Full devices or partial device portions can be included within or on structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), molecular layer deposition (MLD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

As used herein, the term “molecular layer deposition” (MLD) may refer to a vapor deposition process in which deposition cycles, preferably a plurality of consecutive deposition cycles, are conducted in a process chamber. Typically, during each cycle an organic precursor is chemisorbed to a deposition surface (e.g., a substrate surface or a previously deposited underlying surface such as material from a previous MLD cycle), typically forming a single molecular layer that does not readily react with additional organic precursor (i.e., a self-limiting reaction). Thereafter, if necessary, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

As used herein, the term “metallic surface” may refer to surfaces including a metallic component, including, but not limited to, metal surfaces, metal oxide surfaces, metal silicide surfaces, metal nitride surfaces, metal carbide surfaces, and mixtures thereof. The term “metallic surface” may can also include a surface of a native oxide of a metallic material.

As used herein, the term “dielectric surface” may refer a surface of dielectric material, including, but not limited to, silicon containing dielectric materials, such as, for example, silicon oxides, silicon nitrides, silicon oxynitrides, silicon oxycarbides, and mixtures thereof. In addition, the term “dielectric surface” may also refer to a surface of metal oxide material, or metal nitride material, or low dielectric constant material (a low-k material), or high dielectric constant material (a high-k material).

As used herein, the term “chalcogen reactant” may refer to a reactant (also referred to as a precursor) containing a chalcogen. A chalcogen in the current disclosure is an element from Group 16 of the periodic table of elements selected from a group consisting of sulfur (S), selenium (Se) and tellurium (Te).

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Selectivity of deposition on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material, or may be given as the measured amount of material deposited. In embodiments described herein, selective deposition of a passivation layer can be conducted on a first dielectric surface (A) relative to a second metallic surface (B). Subsequently, a target film may be selectively deposited on the second metallic surface (A) relative to the passivation film (B).

In some embodiments, selectivity for the selective deposition of the passivation layer on the first dielectric surface (relative to the second metallic surface) is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%.

In some embodiments, deposition only occurs on the first surface and does not occur on the second surface. In some embodiments, deposition on surface A of the substrate relative to surface B of the substrate is at least about 80% selective, which may be selective enough for some particular applications. In some embodiments, the deposition on the surface A of the substrate relative to surface B of the substrate is at least about 50% selective, which may be selective enough for some particular applications. In some embodiments the deposition on surface A of the substrate relative to the surface B of the substrate is at least about 10% selective, which may be selective enough for some particular applications. The skilled artisan will appreciate that a partially selective process can result in a fully selective structure by a post-deposition etch that removes all of the deposited material from over surface B without removing the entirety of the deposited material from over surface A.

The embodiments of the present disclosure include methods for the selective formation of a passivation layer on a dielectric surface relative to a metallic surface. For example, the embodiments of the present disclosure can include, contacting a metallic surface with a chalcogen reactant and in doing so converting the metallic surface to a metal chalcogenide layer including a passivated metal chalcogenide surface. The passivated metal chalcogenide surface can enable the selective deposition of an organic passivation layer on the dielectric surface relative to the passivated metal chalcogenide surface. For example, the passivated metal chalcogenide surface may prevent, or least delay, nucleation of the passivation layer on the passivated metal chalcogenide surface. Once the selective passivation layer is deposited, the metal chalcogenide layer can be selectively removed to expose the underlying metallic surface. In subsequent processes, a target film can be deposited on the exposed metallic surface thereby enabling metal-on-metal and dielectric-on-metal selective deposition processes.

Methods for selectively forming a passivation layer by vapor deposition techniques are disclosed and described in U.S. Pat. No. 10,373,820, filed on Jun. 1, 2016 (hereinafter the “'769 patent”), the entire disclosure of which is incorporated herein by reference for all purposes. Certain methods for forming a passivation layer are disclosed in the '769 patent and therefore the present disclosure summarizes such disclosure when needed in the interest of brevity and in particular the present disclosure describes in detail the additional and novel methods employed herein for improved methods for selectively forming passivation layers and utilizing said passivation layers.

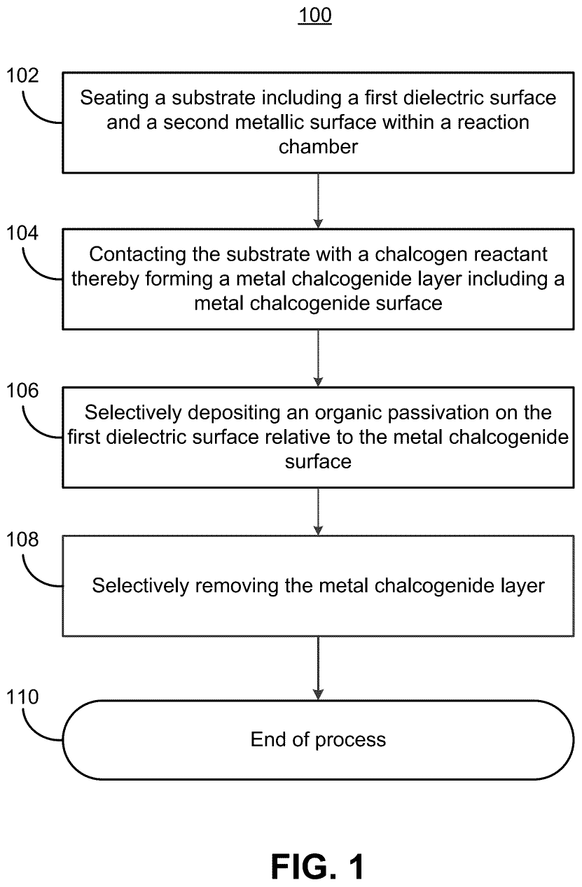

In more detail, FIG. 1 illustrates an exemplary process 100 for selectively forming a passivation layer on a dielectric surface relative to a metallic surface. The exemplary process 100 may commence with the process step 102 comprising, seating a substrate including a first dielectric surface and a second metallic surface within a reaction chamber.

The substrates of the present disclosure may comprise a plurality of first dielectric surfaces and a plurality of second metallic surfaces. For example, the substrate can include dielectric surfaces of low dielectric constant materials, i.e., a low-k material, which may be defined as a material with a dielectric constant less than about 4.0. In some embodiments, the first dielectric surface may comprise a silicon containing surface, such as, for example, a silicon oxide, a silicon nitride, a silicon carbide, a silicon oxynitride, a silicon oxycarbide, or mixtures thereof. In some embodiments, the first dielectric surface may comprise a metal oxide, a metal nitride, a semi-metal oxide, or a semi-metal nitride.

In some embodiments, the second metallic surface can include an elemental metal, such as, for example, copper (Cu), molybdenum (Mo), cobalt (Co), nickel (Ni), or tungsten (W). In some embodiments, the metallic surface may comprise a transition metal, such as, for example, titanium (Ti), vanadium (V), chromium (Cr), manganese (Mn), niobium (Nb), molybdenum (Mo), ruthenium (Ru), rhodium (Rh), palladium (Pd), silver (Ag), gold (Au), hafnium (Hf), tantalum (Ta), tungsten (W), rhenium (Re), osmium (Os), iridium (Ir), or platinum (Pt). In some embodiments, the second metallic surface can include a native metal oxide.

The process step 102 (FIG. 1) may further comprise, seating the substrate within a suitable reaction chamber. The reaction chamber may be configured for performing all, or a portion, of the remaining process steps of exemplary process 100. Reactors and associated reaction chamber(s) capable of the selective formation of passivation layers according to the embodiments of the present disclosure may include reaction chambers configured to perform cyclical deposition processes, such as, for example reaction chambers configured to perform atomic/molecular layer deposition (ALD/MLD) processes, reaction chambers configured to perform plasma enhanced atomic layer deposition (PEALD) processes, as well as reaction chambers configured to perform cyclical chemical vapor deposition (CCVD) processes.

Once the substrate is seated within the reaction chamber it may be heated to a suitable process temperatures. In some embodiments, the methods of the present disclosure may employ two or more different process temperatures. For example, the process temperature, and particularly the substrate temperature, can be modified depending on the particular process step being performed within the reaction chamber. The specifics of the process temperatures employed for particular process steps of exemplary process 100 are described in greater detail herein below.

In addition to controlling the process temperature(s), the pressure in the reaction chamber may also be regulated to enable selective forming of a passivation layer. For example, in some embodiments of the disclosure, the pressure within the reaction chamber may be less than 760 Torr, or between 0.1 Torr and 10 Torr, or between 0.5 Torr and 5 Torr, or between 1 Torr to 4 Torr.

The exemplary process 100 (FIG. 1) may continue with the process step 104 comprising, contacting the second metallic surface with a chalcogen reactant thereby forming a metal chalcogenide layer including a metal chalcogenide surface.

In more detail, the process step 104 may comprise heating the substrate (and/or the reaction chamber) to a first process temperature prior to contacting the second metallic surface with the chalcogen reactant. For example, in some embodiments, heating the substrate to the first process temperature may comprise heating the substrate to a temperature between 50° C. and 600° C., or between 100° C. and 500, ° C., or between 200° C. and 500° C., or even heating the substrate to a temperature between 350° C. and 450° C. Of course, the appropriate temperature window for performing the process step 104 can depend upon the composition of the second metallic surface, the surface termination of the second metallic surface, and the selected chalcogen reactant(s). In some embodiments, the first process temperature varies depending on the chalcogen reactant being used and is generally at or below 700° C. In some embodiments, the first process temperature is at or above 100° C. In some embodiments, the first process temperature can be below 500° C., or below 475° C., or below 450° C., or below 425° C., or below 400° C., or below 375° C., or below 350° C., or below 325° C. or below 300° C.

Once the first process temperature has been attained, the process step 104 can further comprise, contacting the substrate with a chalcogen reactant, and in particular contacting the second metallic surface with a chalcogen reactant.

Any number of chalcogen reactants can be used in the process step 104. For example, the chalcogen reactant may be selected from a group consisting of chalcogenides, chalcogenols, sulfoxides, selenoxides, tellurinyls and elemental chalcogens.

In some embodiments, the chalcogen in the chalcogen reactant has an oxidation state of −2. In some embodiments, the chalcogen in the chalcogen reactant has an oxidation state of +2.

In some embodiments, the chalcogen reactant is a chalcogenide. Examples of chalcogenides include sulfides, selenides and tellurides. The chalcogenide may be an organic chalcogenide. In some embodiments, the chalcogen reactant is a dialkyl chalcogenide. The alkyl groups may be the same or different. Each organic component of the organic chalcogenide may be independently selected from C₁ to C₈ linear, branched, cyclic or aromatic alkyls. An alkyl may be an unsubstituted or substituted hydrocarbon. For example, an organic chalcogen may be dimethyl sulfide, dimethyl selenide, dimethyl telluride, diethyl sulfide, diethyl selenide, diethyl telluride, diisopropyl sulfide, diisopropyl selenide and diisopropyl telluride. The chalcogenide may be an inorganic chalcogenide. An inorganic chalcogenide may be, for example, H₂S, H₂Se, H₂Te, (NH₄)₂S, (NH₄)₂Se or (NH₄)₂Te.

In some embodiments, the chalcogen reactant is a chalcogenol. The chalcogen reactant may be a thiol, a selenol or a tellurol. A chalcogenol may be represented by the formula R—Y—H, wherein R can be a substituted or unsubstituted hydrocarbon, such as a linear, branched, cyclic or aromatic alkyl, and preferably a C₁-C₈ alkyl or substituted alkyl, such as an alkylsilyl group, more preferably a linear or branched C₁-C₅ alkyl group, and Y can be S, Se, or Te.

In some embodiments, the chalcogen reactant is an oxygen-containing chalcogen compound. In some embodiments, the chalcogen reactant comprises a sulfinyl, selenyl or a tellurinyl group. In some embodiments, the chalcogen reactant is represented by the formula Y(O)R₂, wherein Y is S, Se or T, and each R may be independently selected from H and C₁ to C₈ linear, branched, cyclic or aromatic alkyls. An alkyl may be a substituted or unsubstituted hydrocarbon. In some embodiments, the oxygen-containing chalcogen compound is selected from sulfoxides, selenoxides, tellurinyls.

In some embodiments, the chalcogen reactant is an elemental chalcogen. In some embodiments, the chalcogen reactant is elemental sulfur. In some embodiments, the chalcogen reactant is elemental selenium. In some embodiments, the chalcogen reactant is elemental tellurium.

For example, in some embodiments, a chalcogen reactant is selected from the following list: H₂S, H₂Se, H₂Te, (CH₃)₂S, (NH₄)₂S, dimethylsulfoxide ((CH₃)₂SO), (CH₃)₂Se, (CH₃)₂Te, elemental or atomic S, Se, Te, and other precursors containing chalcogen-hydrogen bonds, such as H₂S₂, H₂Se₂, H₂Te₂, or chalcogenols with the formula R—Y—H, wherein R can be a substituted or unsubstituted hydrocarbon, preferably a C₁-C₈ alkyl or substituted alkyl, such as an alkylsilyl group, more preferably a linear or branched C₁-C₅ alkyl group, and Y can be S, Se, or Te. In some embodiments, a chalcogen reactant is a thiol with the formula R—S—H, wherein R can be substituted or unsubstituted hydrocarbon, preferably a C₁-C₈ alkyl group, more preferably a linear or branched C₁-C₅ alkyl group. In some embodiments, a chalcogen reactant has the formula (R₃Si)₂Y, wherein R₃Si is an alkylsilyl group and Y can be S, Se or Te. In some embodiments, a chalcogen reactant comprises S or Se. In some embodiments, a chalcogen precursor comprises S. In some embodiments, a chalcogen precursor does not comprise S. In some embodiments, the chalcogen precursor may comprise an elemental chalcogen, such as elemental sulfur. In some embodiments, a chalcogen precursor does comprise Te. In some embodiments, a chalcogen precursor does not comprise Te. In some embodiments, a chalcogen precursor does comprise Se. In some embodiments, a chalcogen precursor does not comprise Se. In some embodiments, a chalcogen precursor is selected from precursors comprising S, Se and Te. In some embodiments, a chalcogen precursor comprises H₂Sn, wherein n is from 4 to 10. By way of examples, the chalcogen reactant can include one or more reactants, which may comprise hydrogen sulfide (H₂S), hydrogen selenide (H₂Se), dimethyl sulfide ((CH₃)₂S), tert-butylthiol ((CH₃)₃CSH), and/or 2-methylpropane-2-thiol, and dimethyl telluride ((CH₃)₂Te).

In some embodiments, suitable chalcogen reactants may include any number of chalcogen-containing compounds. In some embodiments, a chalcogen reactant may comprise at least one chalcogen-hydrogen bond. In some embodiments, the chalcogen precursor may comprise a chalcogen plasma, chalcogen atoms or chalcogen radicals. In some embodiments where an energized chalcogen reactant is desired, a plasma may be generated in the reaction chamber or upstream of the reaction chamber. In some embodiments, the chalcogen reactant does not comprise an energized chalcogen precursor, such as plasma, atoms or radicals. In some embodiments, the chalcogen reactant may comprise a chalcogen plasma, chalcogen atoms or chalcogen radicals formed from a chalcogen reactant comprising a chalcogen-hydrogen bond, such as H₂S. In some embodiments, a chalcogen reactant may comprise a chalcogen plasma, chalcogen atoms or chalcogen radicals such as a plasma comprising sulfur, selenium or tellurium, preferably a plasma comprising sulfur. In some embodiments, the plasma, atoms, or radicals comprise tellurium. In some embodiments, the plasma, atoms or radicals comprise selenium. In some embodiments, the chalcogen precursor does not comprise a tellurium precursor.

In some embodiments, the chalcogen reactant can comprise an energized (also referred to as activated) chalcogen reactant. In some embodiments, the chalcogen reactant can be energized by applying thermal energy to the chalcogen reactant. In some embodiments, the chalcogen reactant can be energized by irradiating the chalcogen reactant with ultraviolet or laser irradiation. In some embodiments, the chalcogen reactant can be energized by exposing the chalcogen reactant to one or more of a direct plasma or a remote plasma, thereby generating a chalcogen based plasma including chalcogen atoms, chalcogen radicals, chalcogen ions, and chalcogen reactive species. In some embodiments, the chalcogen reactant may be energized by a combination of one or more of the excitation (i.e., activation) processes disclosed herein above.

In some embodiments, the activated chalcogen reactant is activated by exposing the chalcogen reactant to a direct plasma or a remote plasma to thereby form chalcogen based reactive species.

Contacting the second metallic surface with the chalcogen reactant (step 104 of exemplary process 100, illustrated in FIG. 1) can convert the second metallic surface into a self-passivated chalcogenide layer including a metal chalcogenide surface. For example, the reaction between a second metallic surface and a chalcogen reactant can result in a reaction product comprising a metal chalcogenide and due to the expansion of the converted metallic surface the resulting reaction product can comprise a metal chalcogenide layer including a metal chalcogenide surface.

In some embodiments, contacting the substrate with the chalcogen reactant comprises, contacting the substrate with the chalcogen reactant for time period between 0.5 seconds and 10 minutes, or between 1 second and 8 minutes, or between 30 seconds and 5 minute, or between 1 minutes and 3 minutes. In some embodiments, contacting the substrate with the chalcogen reactant comprise, contacting the substrate for time period less than 10 minutes, or less than 8 minutes, or less than 5 minutes, or less than 2 minutes, or less than 1 minute, o less than 30 seconds, or less than 15 seconds, or less than 10 seconds, or less than 5 seconds, or less than 1 second.

In some embodiments, the chalcogen reactant comprises an energized (i.e., an activated) chalcogen reactant and in such embodiments the activated chalcogen reactant may react at a faster rate with the second metallic surface to form the metal chalcogenide layer including the metal chalcogenide surface. Therefore, in some embodiments, contacting the substrate with an activated chalcogen reactant comprises, contacting the substrate with the activated chalcogen reactant for time period between 0.1 seconds and 5 minutes, or between 0.5 seconds and 5 minutes, or between 1 second and 4 minutes, or between 5 seconds and 1 minute. In some embodiments, contacting the substrate with the activated chalcogen reactant comprises, contacting the substrate with the activated chalcogen reactant for time period less than 5 minutes, or less than 3 minutes, or less than 2 minutes, or less than 1 minutes, or less than 30 seconds, or less than 15 seconds, or less than 10 seconds, or less than 5 seconds, or less than 1 second.

Metal chalcogenides may exist in various phases. Unless otherwise indicated, the metal chalcogenide layer is referred to in a general form without specifying a general phase. In some embodiments, a metal chalcogenide is a metal dichalcogenide. In some embodiments, a metal chalcogenide is a metal trichalcogenide. In some embodiments, metal chalcogenide is molybdenum disulfide (MoS₂). In some embodiments, metal chalcogenide is molybdenum trisulfide (MoS₃). In some embodiments, metal chalcogenide is molybdenum diselenide (MoSe₂). In some embodiments, metal chalcogenide is molybdenum ditelluride (MoTe₂). In some embodiments, the metal chalcogenide is tungsten disulfide (WS₂). In some embodiments, the metal chalcogenide is tungsten diselenide (WSe₂). In some embodiments, the metal chalcogenide is tungsten ditelluide (WTe₂). In some embodiments, the metal chalcogenide is tantalum disulfide (TaS₂). In some embodiments, the metal chalcogenide is niobium disulfide (NbS₂). In some embodiments, the metal chalcogenide is niobium trisulfide (NbS₃). In some embodiments, the metal chalcogenide is niobium triselenide (NbSe₃). In some embodiments, the metal chalcogenide is titanium disulfide (TiS₂). In some embodiments, the metal chalcogenide is titanium trisulfide (TiS₃). In some embodiments, the metal chalcogenide is titanium diselenide (TiSe₂). In some embodiments, the metal chalcogenide is titanium tritelluride (TiTe₃). In some embodiments, the metal chalcogenide layer consists essentially of or consists of one metal chalcogenide. In some embodiments, the metal chalcogenide layer consists essentially of or consists of two metal chalcogenides. In some embodiments, the metal chalcogenide layer consists essentially of or consists of two or more metal chalcogenides.

Thus, in some embodiments, the metal chalcogenide according to the current disclosure is a transition metal sulfide. In some embodiments, the metal chalcogenide according to the current disclosure is a transition metal telluride. In some embodiments, the metal chalcogenide according to the current disclosure is a transition metal selenide. In some embodiment, the metal chalcogenide layer can comprise a 2D dichalcogenide layer. In some embodiments, the metal chalcogenide layer can comprise a transition metal dichalcogenide (TMDC) represented by the formula MXₙ, where M represents a transition metal (e.g., a group 5 metal) and X represents a chalcogen, such as, sulfur, selenium, or tellurium, and n indicates the number of chalcogens. In particular embodiments, the metal chalcogenide layer comprises a self-passivated 2D dichalcogenide layer selected from the group consisting of MoS₂, WS₂, and WSe₂.

Upon contacting the second metallic surface with the chalcogen reactant (step 104), the reaction chamber may be purged of any excess reactant and/or reaction by-products.

The exemplary process 100 (FIG. 1) may continue by means of a process step 106 comprising, selectively depositing a passivation layer (e.g., an organic passivation layer) on the first dielectric surface relative to the metal chalcogenide surface. In some embodiments, selectively depositing the organic passivation layer on the first dielectric surface relative to the metal chalcogenide surface comprises, performing multiple deposition cycles of a cyclical deposition process in which the substrate is alternately and sequentially contacted with a first vapor phase organic precursor and second vapor phase organic precursor.

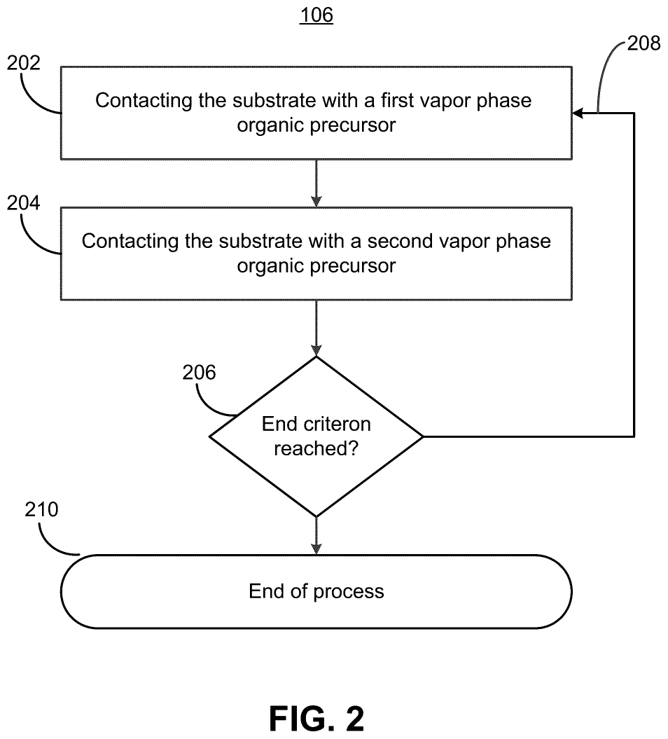

Details relating to methods for selectively depositing an organic passivation layer are described in detail in the '769 patent and are therefore briefly reviewed herein with reference FIG. 2, which illustrates an exemplary selective cyclical deposition process (step 106 and the associated sub-steps of process step 106) for selectively depositing an organic passivation layer on a first dielectric surface relative to a metal chalcogenide surface.

In some embodiments, the selective cyclical deposition process of step 106 may be performed at a second process temperature. For example, in some embodiments, the step of contacting the substrate with the chalcogen reactant (step 104) comprises, heating the substrate to a first process temperature, and the step of selectively depositing the organic passivation layer (step 106) comprises, heating the substrate to a second process temperature, wherein the first process temperature is higher than the second process temperature.

For example, in some embodiments, heating the substrate to a second process temperature may comprise heating the substrate to a temperature greater than 0° C., or less than 500° C., or less than 400° C., or less than 300° C., or less 200° C., or less than 100° C., or less than 50° C., or less than 20° C., or between 20° C. and 500° C., or be 50° C. and 400° C., or between 75° C. and 300° C., or between 100° C. and 200° C.

In some embodiments, contacting the substrate with an activated chalcogen reactant can be performed at a first process temperature, and selectively depositing the organic passivation layer can be performed at second process temperature, wherein the first process temperature and the second process temperature are different.

Upon heating the substrate to the second process temperature the embodiments of the present disclosure may continue with a method for selectively depositing an organic passivation layer on the first dielectric surface relative the metal chalcogenide surface. In some embodiments, the selective deposition of the organic passivation layer can comprise, contacting the substrate with a first vapor phase organic precursor (sub-step 202 of FIG. 2). In some embodiments, the first vapor phase organic precursor can comprise an organic reactant such as a diamine, such as, for example, 1,6-diaminohexane (DAH), or any other monomer with two reactive groups. In some embodiments, the first vapor phase organic precursor may comprise a diamine and may be vaporized to produce a first vapor phase organic precursor comprising a diamine vapor which is transported to the reaction chamber and contacts the substrate.

In some embodiments, the first vapor phase organic precursor, may contact the substrate for time period between 0.01 seconds and 60 seconds, or between 0.05 seconds and 30 seconds, or between 0.1 and 10 seconds, or between 0.2 seconds and 5 seconds. In some embodiments, where batch reactors may be used, exposure periods of greater than 60 seconds may be employed.

Upon contacting the substrate with the first vapor phase organic precursor (sub-step 202 of FIG. 2), the reaction chamber may be purged of any excess reactant and/or reaction by-products.

The selective cyclical deposition process 106 (FIG. 2) can continue with a sub-step 204 comprising, contacting the substrate with a second vapor phase organic precursor. For example, in some embodiments, the second vapor phase organic precursor can comprise an anhydride, such as furan-2,5-dione (maleic acid anhydride) and methods may comprise vaporizing the anhydride and transporting the anhydride vapor to the reaction chamber and contacting the substrate with the anhydride vapor. In some embodiments of the disclosure, the anhydride may comprise a dianhydride, e.g., pyromellitic dianhydride (PMDA), or any other monomer with two reactive groups which will react with the first vapor phase organic precursor.

In some embodiments, the second vapor phase organic precursor, may contact the substrate for time period between 0.01 seconds and 60 seconds, or between 0.05 seconds and 30 seconds, or between 0.1 and 10 seconds, or between 0.2 seconds and 5 seconds. In some embodiments, where batch reactors may be used, exposure periods of greater than 60 seconds may be employed.

Upon contacting the substrate with the second vapor phase organic precursor (sub-step 204), the reaction chamber may be again purged of any excess precursor and/or reaction by-products.

The exemplary selective cyclical deposition process 106 (FIG. 2) may continue via a decision gate 206, wherein the decision gate is dependent on reaching a predetermined end of process criterion, where if the end of process criterion is attained, the cyclical deposition process 106 terminates via the end of process sub-step 210, whereas if the end of process criterion is not attained then the selective cyclical deposition process 106 can continue via the cyclical process loop 208 and one or more further deposition cycles can be performed until the end criterion is successfully attained.

In some embodiments, the end criterion for ending the exemplary cyclical process 106 may comprise, reaching a predetermined thickness of the passivation layer on the first dielectric surface relative to the metal chalcogenide surface. In some embodiments, the end criterion for ending the exemplary selective cyclical deposition process 106 may comprise, performing a predetermined number of deposition cycles.

For example, if the end criterion is not satisfied, then the exemplary cyclical deposition process 106 (FIG. 2) may continue via the cyclical process loop 208 and one or more further deposition cycles may be performed by repeated performing the sub-step 202 and the sub-step 204.

Therefore, in some embodiments, a deposition cycle may be repeated one or more times until a passivation layer of sufficient thickness is deposited on the first dielectric surface and/or a predetermined number of deposition cycles have been performed. For example, in some embodiments, the selective cyclical deposition process 106 (FIG. 2) may comprise, from at least 10 to at most 30000 deposition cycles, or from at least 10 to at most 3000 deposition cycles, or from at least 10 to at most 1000 deposition cycles, or from at least 10 to at most 500 deposition cycles, or from at least 20 to at most 200 deposition cycles, or from at least 50 to at most 150 deposition cycles, or from at least 75 to at most 125 deposition cycles, for example 100 deposition cycles.

The deposition cycles of selective cyclical deposition process 106 (FIG. 2) can include additional sub-steps (not shown), and need not be in the same sequence nor identically performed in each repetition, and can be readily extended to more complex vapor deposition techniques. For example, a selective cyclical deposition cycle can include additional reactant/precursor supply processes, such as the supply and removal of additional reactants/precursors in each cycle or in selected cycles.

In some embodiments, the organic passivation layer can be selectively deposited on the first dielectric surface relative to the metal chalcogenide surface and may have an average thickness of less than 100 nanometers, or less 50 nanometers, or less than 20 nanometers, or less than 10 nanometers, or less than 5 nanometers, or less than 3 nanometers, or less than 2 nanometers, or less than 1 nanometer, or even between 1 nanometer and 50 nanometers.

In some embodiments, the ratio of material deposited on the first dielectric surface relative to the metal chalcogenide surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1.

In some embodiments, the selectivity of the methods of present disclosure for selectivity forming an organic passivation layer on a first dielectric surface relative to a metal chalcogenide surface can be greater than 10%, or greater than 50%, or greater than 75%, or greater than 85%, or greater than 90%, or greater than 93%, or greater than 95%, or greater than 98%, or greater than about 99%, or even greater than 99.5%. Therefore, in some embodiments, an organic passivation layer can be deposited preferentially on a first dielectric surface relative to a metal chalcogenide surface with a selectivity above 50%.

Referring back to exemplary process 100 of FIG. 1. After the selective deposition of the organic passivation layer has been performed, the exemplary process 100 (FIG. 1) may continue by means of process step comprising, selectively removing the metal chalcogenide layer. In some embodiments, selectively removing the metal chalcogenide layer further comprising selectively removing the entirety of the metal chalcogenide layer thereby exposing the underlying metallic layer, wherein the exposed surface of the underlying metallic layer can comprise a third metallic surface. For example, the original second metallic surface is converted to form the metal chalcogenide layer and the process of selectively removing of the metal chalcogenide layer re-exposes the underling metallic layer, however, the newly exposed surface is not the same surface as the original second metallic surface and therefore is referred to herein as the third metallic surface. In some embodiments of the disclosure, selectively removing the metal chalcogenide layer can further comprise selectively removing the metal chalcogenide layer without removing any, or without removing a significant amount, of the organic passivation layer. For example, selectively removing the metal chalcogenide layer can further comprise, removing less than 30%, or less than 20%, or less than 10%, or than 5%, or less than 2%, or less than 1%, or less than 0.5% of the average thickness of the passivation layer.

In some embodiments, selectively removing the metal chalcogenide layer can comprise, contacting the metal chalcogenide with a reducing agent or an etchant. In some embodiments, selectively removing the metal chalcogenide layer can comprise, contacting the metal chalcogenide with a vapor phase reducing agent or a vapor phase etchant.

In some embodiments, selectively removing the metal chalcogenide layer comprises, contacting the substrate with a reactive species generated by a plasma (either remotely or directly).

For example, selectively removing the metal chalcogenide layer can comprise, contacting the substrate with a plasma generated from a hydrogen containing gas, and in such embodiments the reactive species can comprise hydrogen ions and hydrogen radicals. In some embodiments, selectively removing the metal chalcogenide layer comprises, contacting the substrate with a plasma generated from a halide containing gas, and in such embodiments the reactive species can comprise halide ions and halide radicals. In some embodiments, selectively removing the metal chalcogenide layer comprises, contacting the substrate with a plasma generated from a chlorine containing gas, and in such embodiments the reactive species can comprise chlorine ions and chlorine radicals. In some embodiments, selectively removing the metal chalcogenide layer comprises, contacting the substrate with a plasma generated from a gas containing argon and chlorine and in such embodiments the reactive species can comprise chlorine ions, chlorine radicals, argon ions, and argon radicals. In some embodiments, the one or more reactive species employed to selectively remove the metal chalcogenide layer are generated from a gas including, hydrogen, argon, a halide containing gas, and mixture and combinations thereof.

After completing the process step 108 (FIG. 1) comprising, selectively removing the metal chalcogenide layer, the exemplary process can end via the end of process step 110 and the substrate with a surface comprising a passivation layer and a third metallic surface may be subjected to additional process steps, such as, for example, process steps utilized in the fabrication of semiconductor devices and/or integrated circuits.

The exemplary process 100 of FIG. 1 for selectively forming passivation layer on a dielectric surface relative to a metallic surface can include additional steps (not shown), and need not be in the same sequence nor identically performed, and can be readily extended to more complex vapor deposition techniques. For example, in some embodiments, prior to contacting the substrate with the chalcogen reactant (step 104) an additional process step can comprise, performing a surface clean on at least the second metallic surface prior to contacting the substrate with the chalcogen reactant, wherein the surface clean step can remove a native oxide from the surface of the second metallic surface. As a non-limiting example, performing a surface clean may comprise, contacting the substrate, and particular the second metallic surface, with a vapor phase etchant, or a vapor phase reducing agent, or reactive species generated from a plasma, such as, hydrogen reactive species generated from a gas including hydrogen.

The embodiments of the present disclosure can also include methods for not only selectively forming a passivation layer on dielectric surface relative to a metallic surface but can also include methods that utilize said selective passivation layers.

Therefore in some embodiments, methods for selectively forming and utilizing a passivation layer on a substrate are disclosed. For example, the methods can comprise, seating a substrate including a first dielectric surface and a second metallic surface within a reaction chamber, contacting the substrate with an activated chalcogen reactant, thereby converting the second metallic surface to a metal chalcogenide layer including a metal chalcogenide surface. The methods can further include, selectively depositing an organic passivation layer on the first dielectric surface relative to the metal chalcogenide surface by performing multiple deposition cycles of a cyclical deposition process in which the substrate is alternately and sequentially contacted with a first vapor phase organic precursor and a second vapor phase organic precursor. The methods can also include, selectively removing the metal chalcogenide layer by contacting the substrate with one or more reactive species generated from a plasma thereby exposing a third metallic. The methods can also include selectively depositing a target film on the third metallic surface and selectively removing the organic passivation layer relative to the target film.

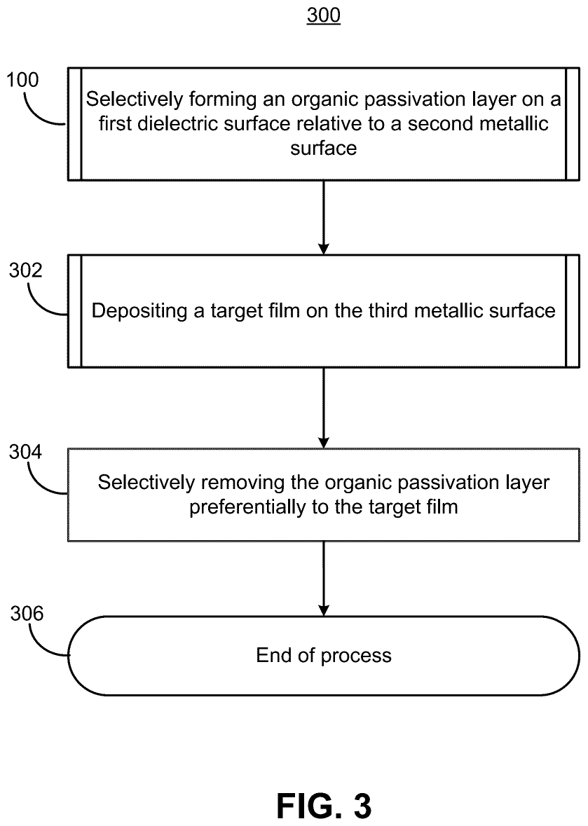

In more detail, FIG. 3 illustrates a second exemplary process 300 that can commence by selectively depositing a passivation layer on a dielectric surface relative to a metallic surface (process step 100), as previous described herein above with reference to FIG. 1 and exemplary process 100.

In some embodiments, the second exemplary process 300 may continue with a process step 302 comprising, depositing a target film on the second metallic surface. In some embodiments, the target film may comprise a dielectric film thereby enabling a dielectric-on-metal selective process, or the target film may comprise a metal (or metallic) film, thereby enabling a metal-on-metal selective process. In some embodiments, the target film comprises one of a dielectric film, an organic film, a metallic film, and a metal oxide film.

In some embodiments, the target film may be deposited in the same reaction chamber utilized for the formation of the selective passivation layer or alternatively the substrate may be transferred to a second reaction chamber (e.g., under a controlled atmosphere). In some embodiments, the target film may be deposited by cyclical deposition methods, such as, for example, atomic layer deposition (ALD), or cyclical chemical vapor deposition (CCVD).

In some embodiments, the target film can be deposited by performing a plurality of deposition cycles of a cyclical deposition process in which the substrate is alternately and sequentially contacted with a first vapor phase reactant, and a second vapor phase reactant.

After the deposition of the target film the exemplary process 300 can continue with a process step 304 comprising, selectively removing the organic precursor preferentially to the target film. For example, the organic precursor may be selectively removed by contact the substrate with one or more of a vapor phase reducing agent, a vapor phase reactant, or reactive species generated from a plasma.

Details of processes for forming a target film and particular methods for selectively forming a target film on a selective passivation layer are described in detail in the '769 patent and are therefore are not repeated herein in interest of brevity. Once the target film has been deposited to a desired thickness (step 302) and the organic precursor has selectively been removed (step 304), the exemplary second process 300 may end via the end of process step 306.

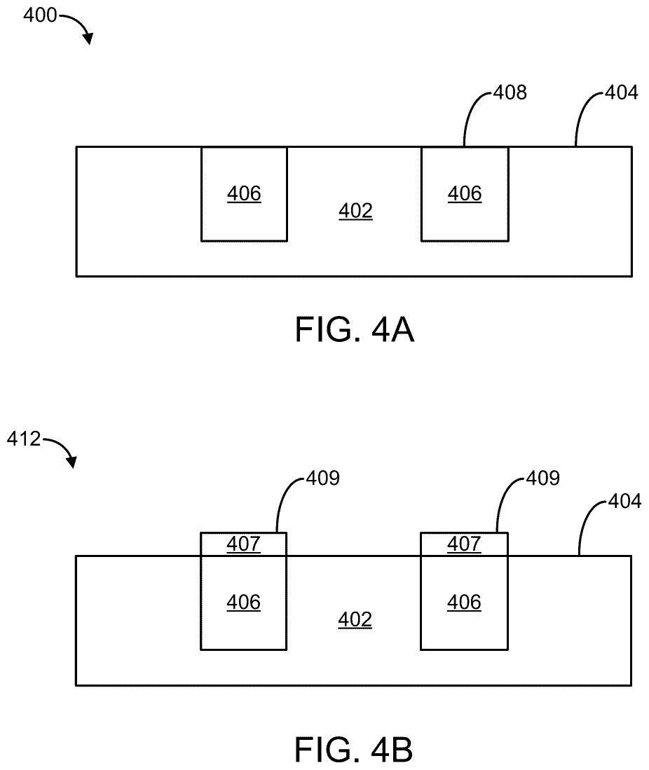

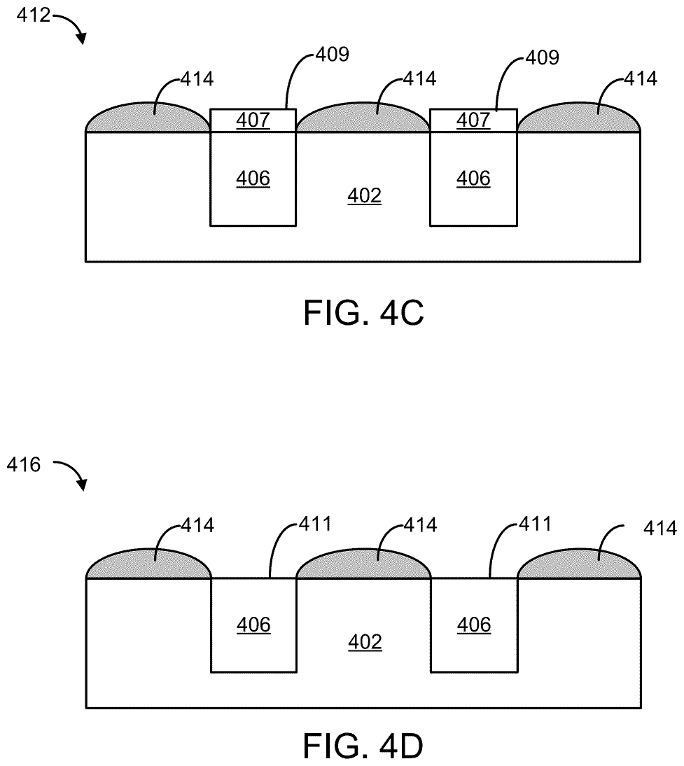

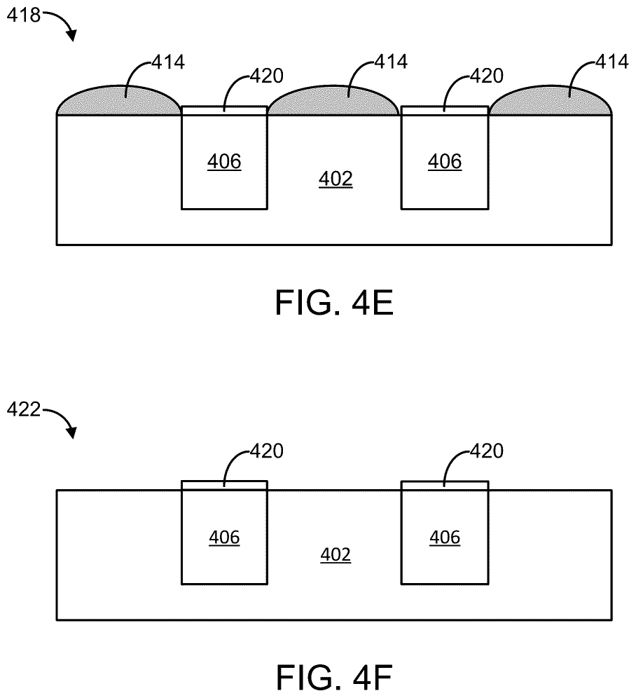

The present disclosure also includes structures formed according to the methods of the present disclosure. For example, FIGS. 4A-F illustrate exemplary cross-sectional views of structures formed by methods of the present disclosure.

In more detail, FIG. 4A illustrates a structure 400 that includes, a dielectric material 402 with a first dielectric surface 404. The dielectric material 402 may comprise, a low-k dielectric material, for example. The structure 400 can also include metallic features 406, such as, molybdenum or tungsten, for example. The metallic features 406 can also comprise an exposed second metallic surface 408.

FIG. 4B illustrates structure 410 which comprises the structure 400 of FIG. 4A after contacting the substrate with a chalcogen reactant. For example, structure 410 includes a metal chalcogenide layer 407 including a metal chalcogenide surface 409 both formed by conversion of the second metallic surface 408 (of FIG. 4A) after reacting with the chalcogenide reactant.

FIG. 4C illustrates structure 412 which comprises the structure 410 of FIG. 4B after the selective deposition of the passivation layer on the first dielectric surface 404 (FIG. 4A) relative to the metal chalcogenide surface 409 (FIG. 4B) according to methods of the present disclosure. As illustrated in FIG. 4C, the passivation layer 414 is selectively disposed over the dielectric surfaces relative to the metal chalcogenide surfaces. As a non-limiting example, the passivation film layer 414 may comprise an organic polyimide film deposited according to the embodiments of the present disclosure.

FIG. 4D illustrates a structure 416 which comprises the structure 412 of FIG. 4C after the selective removal of the metal chalcogenide layer. As illustrated in FIG. 4D, the metal chalcogenide layer is completely removed and a third metallic surface 411 is exposed without the removal of any, or without the removal of a significant percent thickness of the passivation layer 414.

FIG. 4E illustrates a structure 418 which comprises a target film 420 disposed directly on the surface of metallic features 406 between the passivation layer 414 disposed over the surface of dielectric material 402. As a non-limiting example, the target film 320 may comprise a metal, a metal oxide film, or a dielectric film deposited utilizing cyclical deposition processes.

FIG. 4F illustrates a structure 422 which comprises the structure 418 (FIG. 4E) after the selective removal of the passivation layer 414 while maintaining a thickness of the target film 420 disposed over the and metallic features 406.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation

What is claimed is:

1. A method for selectively forming a passivation layer on a dielectric surface relative to a metallic surface on a substrate, the method comprising:
seating a substrate including a first dielectric surface and a second metallic surface within a reaction chamber;
contacting the second metallic surface with a chalcogen reactant thereby forming a metal chalcogenide layer including a metal chalcogenide surface;
selectively depositing an organic passivation layer on the first dielectric surface relative to the metal chalcogenide surface; and
selectively removing the metal chalcogenide layer.

2. The method of claim 1, further comprising, performing a surface clean step on a surface of the substrate prior to contacting the substrate with the chalcogen reactant, wherein the surface clean step removes a native oxide from the second metallic surface.

3. The method of claim 1, wherein the chalcogen reactant comprises one or more of a sulfur reactant, a selenium reactant, and a tellurium reactant, or combinations thereof.

4. The method of claim 1, wherein chalcogen in the chalcogen reactant has an oxidation state of −2.

5. The method of claim 1, wherein chalcogen in the chalcogen reactant has an oxidation state of +2.

6. The method of claim 3, wherein the chalcogen reactant is selected from a group consisting of chalcogenides, chalcogenols, sulfoxides, selenoxides, tellurinyls and elemental chalcogens.

7. The method of claim 1, wherein the chalcogen reactant comprises one or more of H₂S, H₂Se, H₂Te, (CH₃)₂S, (NH₄)₂S, dimethylsulfoxide ((CH₃)₂SO), (CH₃)₂Se, (CH₃)₂Te, elemental or atomic S, Se, Te, H₂S₂, H₂Se₂, H₂Te₂, a chalcogenol with a formula R—Y—H, wherein R is a substituted or a unsubstituted hydrocarbon selected from a C₁-C₈ alkyl or substituted alkyl, and Y is S, Se, or Te, a thiol with a formula R—S—H, wherein R is substituted or unsubstituted hydrocarbon, and a chalcogen alkylsilyl reactant having a formula (R₃Si)₂Y, wherein R₃Si is an alkylsilyl group and Y is S, Se or Te.

8. The method of claim 1, wherein the chalcogen reactant comprises an energized chalcogen reactant, wherein energizing the chalcogen reactant comprises one or more of applying thermal energy to the chalcogen reactant, irradiating the chalcogen reactant with UV or laser irradiation, and generating a plasma from the chalcogen reactant to form chalcogenide based reactive species.

9. The method of claim 1, wherein selectively depositing the organic passivation layer on the first dielectric surface relative to the metal chalcogenide surface comprises, performing multiple deposition cycles of a cyclical deposition process in which the substrate is alternately and sequentially contacted with a first vapor phase organic precursor and a second vapor phase organic precursor.

10. The method of claim 9, wherein the first vapor phase organic precursor comprises a diamine, the second vapor phase organic precursor comprises a dianhydride, and the organic passivation layer comprises a polyimide.

11. The method of claim 1, wherein selectively removing the metal chalcogenide layer comprises contacting the substrate with a plasma generated from a gas comprising hydrogen, argon, a halide containing gas, or mixtures and combinations thereof.

12. The method of claim 1, wherein the metal chalcogenide layer comprises one of MoS₂, WS₂, and WSe₂.

13. The method of claim 1, wherein contacting the second metallic surface with the chalcogen reactant is performed at a first process temperature, and selectively depositing the organic passivation layer is performed at a second process temperature, herein the first process temperature is higher than the second process temperature.

14. A method for selectively forming and utilizing a passivation layer on a substrate, the method comprising:
seating a substrate including a first dielectric surface and a second metallic surface within a reaction chamber;
contacting the substrate with an activated chalcogen reactant, thereby converting the second metallic surface to a metal chalcogenide layer including a metal chalcogenide surface;
selectively depositing an organic passivation layer on the first dielectric surface relative to the metal chalcogenide surface by performing multiple deposition cycles of a cyclical deposition process in which the substrate is alternately and sequentially contacted with a first vapor phase organic precursor and a second vapor phase organic precursor;
selectively removing the metal chalcogenide layer by contacting the substrate with one or more reactive species generated from a plasma thereby exposing a third metallic surface;
depositing a target film on the third metallic surface; and
selectively removing the organic passivation layer preferentially to the target film.

15. The method of claim 14, wherein the metal chalcogenide layer comprises a self-passivated 2D dichalcogenide layer selected from the group consisting of MoS₂, WS₂, and WSe₂.

16. The method of claim 14, wherein the activated chalcogen reactant is activated by exposing the chalcogen reactant to a direct plasma or a remote plasma to thereby form chalcogen based reactive species.

17. The method of claim 14, wherein contacting the substrate with the activated chalcogen reactant is performed at a first process temperature, and selectively depositing the organic passivation layer is performed at a second process temperature, wherein the first process temperature and the second process temperature are different.

18. The method of claim 14, wherein the activated chalcogen reactant contacts the substrate for time period between 1 minute and 10 minutes.

19. The method of claim 14, the one or more reactive species employed to selectively remove the metal chalcogenide layer are generated from a gas including, hydrogen, argon, a halide containing gas, and mixture and combinations thereof.

20. The method of claim 14, wherein selectively removing the metal chalcogenide layer further comprises, removing less than 10% of an average thickness of the organic passivation layer.
